(19) United States
(12) Patent Application Publication
(10) Pub. No.: US 2002/0195928 A1
(43) Pub. Date: Dec. 26, 2002

(54) Electroluminescent display device and method of making

(76) Inventors: Anthony J. Grace, Long Beach, CA (US); Kieran F. Drain, Newhall, CA (US); Yukihiko Sasaki, Claremont, CA (US)

Correspondence Address: RENNER OTTO BOISSELLE & SKLAR, LLP, 1621 EUCLID AVENUE, NINETEENTH FLOOR, CLEVELAND, OH, 44115, US

(21) Appl. No.: 09/961,844

(22) Filed: Sep. 24, 2001

Related U.S. Application Data
(60) Provisional application No. 60/300,682, filed on Jun. 25, 2001.

(51) Int. Cl. H05B 33/00

(52) U.S. Cl. 313/503

(57) ABSTRACT

An electroluminescent display includes a pair of panels with respective corresponding substrates. At least one of the substrates has an array of microreplicated protrusions to maintain the substrates a desired distance apart from one another. The protrusions may be ridges surrounding each of a plurality of wells in which electrodes and light emitting material is located. The protrusions may be in formed in a flexible substrate by a roll embossing process. The electroluminescent display may be any of a variety of types of displays, for example polymer light emitting devices (PLEDs) or organic light emitting devices (OLEDs).

This application claims the benefit of U.S. Provisional Application No. 60/300,682, filed Jun. 25, 2001, which is incorporated by reference in its entirety.

### BACKGROUND OF THE INVENTION

1. Technical Field of the Invention

The invention relates to optical display devices, and to methods for making the same.

2. Background of the Related Art

Electroluminescent display devices utilize light emitting materials to selectively display information. Currently-utilized types of electroluminescent displays include organic light emitting devices (OLEDs) and polymer light emitting device (PLEDs).

It is desirable to be able to manufacture large area displays of relatively light weight for use in portable devices such as computers, electronic books, personal digital assistants, and the like. Certain organic, polymeric substrates are much lighter than glass while being transparent and are therefore preferred for use over glass in large area, lightweight displays. However, one problem with polymeric substrate displays is the difficulty of properly aligning such substrates, especially if both films are produced using roll-to-roll formation processes. In addition, there may be problems in maintaining desired separation between the substrates, especially if flexible substrates are utilized.

### SUMMARY OF THE INVENTION

An electroluminescent display includes a pair of panels with respective corresponding substrates. At least one of the substrates has an array of microreplicated protrusions to maintain the substrates a desired distance apart from one another. The protrusions may be ridges surrounding each of a plurality of wells in which electrodes and light emitting material is located. The protrusions may be in formed in a flexible substrate by a roll embossing process. The electroluminescent display may be any of a variety of types of displays, for example polymer light emitting devices (PLEDs) or organic light emitting devices (OLEDs).

According to an aspect of the invention, an electroluminescent display includes a first substrate having protrusions on a major surface thereof; a second substrate resting at least partially on the protrusions; and a plurality of pixels between the substrates, each of the pixels including a light emitting material between a pair of electrodes.

According to another aspect of the invention, a method of making an electroluminescent display device includes the steps of 1) forming a pair of panels, wherein one of the panels includes overlapping electrodes with light emitting material therebetween, the electrodes and the light emitting material thereby forming a plurality of pixels, and wherein at least one of the panels includes protrusions; and 2) joining the panels together such that the protrusions maintain a space between opposing major surfaces of the panels, with the electrodes and the light emitting material between the major surfaces of the panels.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

In the annexed drawings:

FIG. 1 is a schematic cross-sectional view of an electroluminescent device in accordance with the present invention;

FIG. 2 is a schematic cross-sectional view of an electroluminescent device back panel in accordance with the present invention;

FIG. 3 is a schematic cross-sectional view of an alternate embodiment electroluminescent device in accordance with the present invention;

FIG. 4 is a schematic illustration of some of the steps of the fabrication if the device of FIG. 3;

FIG. 5 is an illustration of a machine used to produce the protrusions of the flexible substrate of the device of FIG. 3;

FIG. 6 is an illustration of an embossing machine used in producing a rigid substrate with protrusions;

FIG. 7 is a schematic cross-sectional view of another alternate embodiment electroluminescent device in accordance with the present invention;

FIG. 8 is a schematic cross-sectional view of yet another alternate embodiment electroluminescent device in accordance with the present invention;

FIG. 9 is a plan view of a microreplicated substrate film in accordance with the present invention;

FIGS. 10 and 11 are cross-sectional views along directions 10-10 and-11-11, respectively, of FIG. 9;

FIG. 12 is a plan view illustrating selective etching of an electrode layer on the substrate film of FIG. 9; and

FIG. 13 is a plan view illustrating selective deposition of an insulator on the substrate film of FIG. 9.

### DETAILED DESCRIPTION

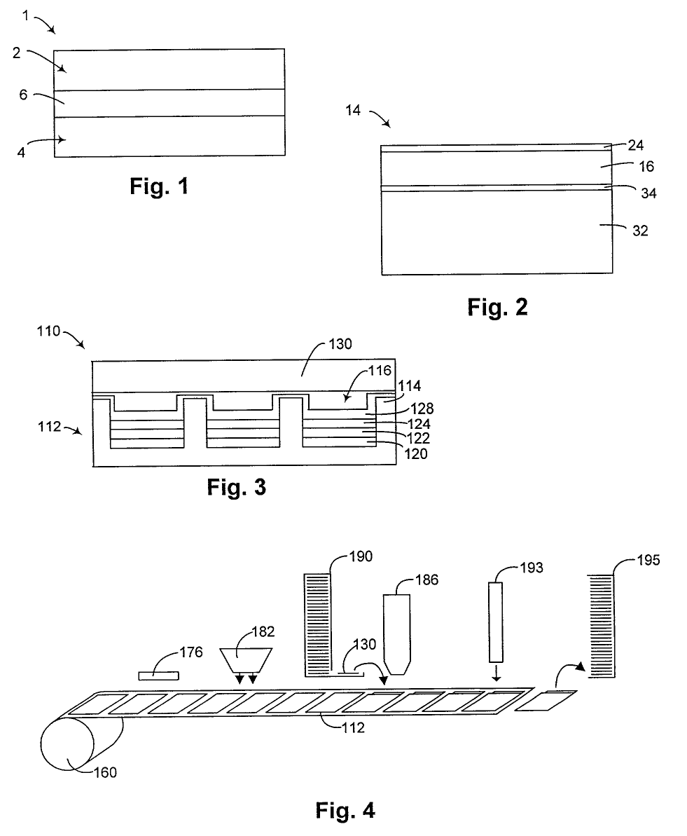

Referring now to FIG. 1, an electroluminescent display device 1 is shown. The electroluminescent display device 1 includes a front substrate 2 and a back substrate 4, with a light emitting structure 6 therebetween. The light emitting structure 6 may include multiple layers, such as an anode, a hole transport layer, an emissive layer, and a cathode. The light emitting structure may also include other layers, such as a hole injection layer and/or an electron transport layer. Some of these layers may be suitably combined. For example, emissive material may be embedded in the electron transport layer. The layers between the anode and the cathode are generally referred to herein as “light emitting material.”

FIGS. 2, 3, and 7-9 show various embodiments of the electroluminescent display device 1 and/or parts thereof. Referring initially to FIG. 2, a back panel 14 for an electroluminescent display device includes an emitter and other layers (indicated generally as 16 and also referred to as a light emitting material) that can be made to electroluminesce by applying a voltage across the material by means of electrodes 24 and 34. As noted above, the layers 16 may include a hole transport material and the emitter. The back panel 14 may be part of an organic light emitting device (OLED) or alternatively may be a part of a polymer light emitting device (PLED). When a sufficiently large voltage is applied across the layers 16 by the electrodes 24 and 34, electrons are ejected from one of the electrodes (the cathode) and holes are emitted from the other of the electrodes (the anode). The electron-hole combinations are unstable, and combine in the emitter to release energy in the form of light.

The layers 16 may include any of a variety of suitable materials, such as semiconductor materials; organic compounds such as conjugated organics or conjugated polymers that have many of the characteristics of semiconductors; and suitable polymers such as poly-paraphenylene vinylene (PPV). For an OLED, the hole transport material may have a thickness from 100 to 500 Angstroms, and the emitter may have a thickness from 50 to 100 Angstroms. Further detail on suitable materials may be found in U.S. Pat. No. 5,703,436 and in U.S. Pat. No. 5,965,280, both of which are incorporated by reference in their entireties.

The electrodes 24 and 34 may be arrayed such that various parts of the light emitting material may be selectively actuated to luminesce. Further details regarding a suitable arrangement of electrodes may be found in the above-referenced U.S. Pat. No. 5,703,436.

The electrodes 24 and 34 include transparent electrodes, and may include fully or partially opaque electrodes. Thus the electrodes 24 and 34 may include commonly-known transparent conducting oxides, such as indium tin oxide (ITO). It will be appreciated that other metal oxides may be employed, such as indium oxide, titanium oxide, cadmium oxide, gallium indium oxide, niobium pentoxide, and tin oxide. In addition to a primary oxide, the electrodes may include a secondary metal oxide such as an oxide or cerium, titanium, zirconium, hafnium, and/or tantalum. The possible transparent conductive oxides include ZnO₂, Zn₂SnO₄, Cd₂SnO₄, Zn₂In₂O₅, MgIn₂O₄, Ga₂O₃—In₂O₃, and TaO₃. The electrodes 24 and 34 may be suitably arranged to form a plurality of picture elements (pixels). The electrodes 24 and 34 may be formed, for example, by low temperature sputtering or direct current sputtering techniques (DC-sputtering or RF-DC sputtering), followed by selective removal of material. The electrodes 24 and 34 may have leads that are connected to bus leads, which in turn are connected to addressing electronics. The electrodes 24 and 34 may be addressed independently to create an electric field at selected pixels. In some addressing schemes, the electrodes are sequentially and repeatedly scanned at a rapid rate to provide moving images similar to television images. This requires “refreshing” the display at short time intervals to rapidly turn pixels on and off.

Example materials for opaque electrodes include copper or aluminum. Other possible electrodes are elemental metal electrodes (opaque or transparent) that contain silver, aluminum, copper, nickel, gold, zinc, cadmium, magnesium, tin, indium, tantalum, titanium, zirconium, cerium, silicon, lead, palladium, or alloys thereof. Metal electrodes on plastic film have the advantage of higher conductivity than ITO electrodes on film.

The electrodes may have a variety of suitable surface resistances. For example, the ITO may have a surface resistance from 30 to 60 ohm/square. The silver or silver alloy electrodes may have a surface resistance from 5 to 30 ohm/square. The aluminum electrodes may have a surface resistance from 1 to 30 ohm/square.

The back panel 14 may include a flexible back substrate 32, such as a polymeric film substrate. The back substrate 32 may be made of an optically-transparent thermoplastic polymeric material. Examples of suitable such materials are polycarbonate, polyvinyl chloride, polystyrene, polymethyl methacrylate, polyurethane polyimide, polyester, and cyclic polyolefin polymers. More broadly, the back substrate 32 may be a flexible plastic such as a material selected from the group consisting of polyether sulfone (PES), polyethylene terephthalate (PET), polyethylene naphthalate, polycarbonate, polybutylene terephthalate, polyphenylene sulfide (PPS), polypropylene, aramid, polyamide-imide (PAI), polyimide, aromatic polyimides, polyetherimide, acrylonitrile butadiene styrene, and polyvinyl chloride. Further details regarding substrates and substrate materials may be found in International Publication Nos. WO 00/46854, WO 00/49421, WO 00/49658, WO 00/55915, and WO 00/55916, the entire disclosures of which are herein incorporated by reference in their entireties.

The back substrate 32 may be a transparent polymer film with better than 85% transmission at 530 nm.

Alternatively, the back substrate 32 may be made of a rigid material, such as glass or a rigid plastic. The glass may be a conventionally-available glass, for example having a thickness of approximately 0.2-1 mm. The rigid plastic may have a high glass transition temperature, for example above about 65 degrees C., and may have a transparency greater than 85% at 530 nm.

The back panel 14 may include an acrylic or other hard internal protective layer to facilitate laser ablation of the back electrodes 34. As described in further detail below, laser light such as excimer laser light may be used to pattern the back electrodes 34. The internal protective layer may be a coating to prevent laser light penetrating and damaging functional layers between the internal protective layer and the back substrate 32. Acrylic, like other organic polymers, has a relatively low thermal conductivity, thereby minimizing lateral damage in ablation that may accompany the laser ablation to pattern the back electrodes 34. It will be appreciated that other suitable materials, such as other suitable polymers, may alternatively be included in the internal protective layer.

The back panel 14 may include a barrier coating, such as a multilayer barrier coating, to prevent contaminants, such as water and/or moisture, from entering. The moisture and oxygen barrier may be a conventional suitable material, such as SiO₂. Alternatively, the barrier may be SiOₓ, where 1<x<2. Using SiOₓ instead of SiO₂ may provide an additional moisture and oxygen barrier for the display, better preventing moisture and oxygen from being transported through the display. The value x for the SiOₓ may be controlled, for example, by controlling the oxide ratio in the material used in sputtering the oxide layer, by adding oxygen to an SiO material. As another alternative, a metal film or film-foil laminate, for example a copper or aluminum foil, may be used as a barrier. As still another alternative, the material for the back substrate 32 may be selected to act on its own as a suitable moisture and oxygen barrier. Thus the need for a separate moisture and oxygen barrier may be avoided entirely. For example, a glass front substrate may be sufficiently impermeable to moisture and oxygen to function on its own as a barrier.

The back panel 14 may be opaque. The opaqueness of the back panel 14 may accomplished in any of a variety of way. For example, the back substrate 32 may be made of an opaque material, such as a suitable opaque polymer material, for example one of the transparent polymer materials discussed above to which a dye or other pigmentation is added. Alternatively, the back substrate 32 may include the opaque material layer, which may be a polymer which is the same as or different from the transparent polymer of the remainder of the back substrate 32.

Alternatively or in addition, as noted above, the electrode material for the back electrodes 34 itself may be opaque. For example, the electrode material may be aluminum or copper, which is opaque when deposited on the polymer substrate material. The depositing of the electrode material may be by sputtering, for example.

It will be appreciated that a suitable opaqueness may alternatively be achieved by printing an opaque ink between all or a portion of the back substrate 32 and the back electrodes 34.

As discussed in greater detail below, the substrate 32 may have any of a variety of suitable protrusions therein.

Turning now to FIG. 3, an electroluminescent display device 110 (a passive matrix polymer light emitting device (PLED)) includes a microreplicated substrate film 112. The substrate film 112 has ridges or protrusions 114, and wells 116 between the ridges or protrusions 114. Each of the wells 116 is surrounded with four walls of the ridges 114, thereby forming a separate pixel. In each of the wells 116 are an anode 120, a hole transport layer 122, a light emitting polymer (LEP) 124, and a cathode 128. A rigid back panel 130 protects the back side of the display 110. The substrate film 112 and the back panel 130 are sealed by a sealant such as an epoxy resin (not shown in FIG. 3) to prevent moisture penetration into the display device 110.

It will be appreciated that suitable alternatives may be used for some of the above steps. For example, wet etching may be used instead of one or both of the laser etchings. As another example, sputtering deposition may be used instead of one or both of the inkjet printing processes.

The substrate film 112 may be polycarbonate, PET, or PES. The anode 120 is a transparent electrode, such as an ITO electrode or an electrode composed of silver or silver alloy. Formation of such transparent electrodes is described further in U.S. Pat. No. 5,667,853, which is incorporated herein by reference in its entirety. The hole transport layer 122 may include PEDOTIPSS material (polyethylene dioxy thiophene/polystyrene sulphonate), and may have a thickness from 20 to 60 nm. The LEP 124 may include poly(phenylene vinylene) derivatives, and may have a thickness of less than 200 nm. The cathode 128 may be a low work function electrode material, for example including Ca or Mg.

The back panel 130 may include glass, and may have an opaque coating such as a black coating or a metal coating to improve the contrast ratio of the display device 110. Alternatively, the back panel 130 may be uncoated, non-transparent (such as opaque) glass. As another alternative, the back panel 130 may be a polymer-metal laminate, such as a metal foil layer laminated on a substrate film. The metal foil layer of the laminate may include an aluminum foil, a copper foil, or a stainless steel foil, and may be from 25 to 75 microns thick. The metal foil may function both as a reflective layer and a barrier layer. The substrate film of the laminate may include a polycarbonate film, a PET film, or a PES film, and may have a thickness from 50 to 200 microns. The polycarbonate film may have a glass transition temperature from 120 to 220 degrees C. Suitable polycarbonate films include HA 120 and HT 200 films available from Teijin Limited, of Osaka, Japan. A suitable PET film is a PET film available from DuPont, which is heat stabilized and has a glass transition temperature of 78 degrees C. and a use temperature of up to 120 degrees C.

The ridges or protrusions 114 may have straight sides (as shown in FIG. 3), or alternatively may have tapered sides (as shown in FIGS. 10-13, described below). The process for forming the ridges or protrusions 114 is described in greater detail below. As an alternative to the ridges 114 shown, other suitable protrusions, such as ribs or posts, may be employed.

A potential difference between the anode 120 and the cathode 128 causes flow of electrons through the structure in the well 128, which causes the LEP 124 to emit light. This light passes through the transparent anode 120 and the transparent substrate film 112, and out of the display device 110.

The substrate film 112 may have one or more coatings to provide a barrier against contamination of the display device 110 by oxygen and/or moisture.

A process for making the display device 110 may include forming the anodes 120 in the wells 116 by sputtering ITO followed by laser etching or by sputtering with shadow masking during the sputtering. The hole transport layer 122 and the LEP 124 may by deposited by sequential ink jet printing of PEDOT and LEP into the wells 116. Then sputter coating of the cathodes 128 is followed by placement and sealing of the back panel 130.

More broadly, manufacture of the display 110 may include the following steps: 1) microreplicate the substrate film 112 to form the ridges 114 and the wells 116; 2) sputter coat the material for the anodes 120; 3) laser etch to remove the anode material from the tops and sides of the ridges 114; 4) inkjet print the hole transport layer 122 in the wells 116; 5) inkjet print the LEP 124 in the wells 116; 6) sputter deposit the material for the cathodes 128; 7) laser etch to remove the cathode material from the tops and sides of the ridges 114 (removing excess hole transport layer material and LEP as well); 8) printing the sealant; 9) laminating the back panel 130 onto the ridges 114 by a pick and place operation; 10) curing the sealant; and 11) cutting the finished display device 110, separating it from a roll including multiple such devices. Steps 1, 2, and 3 of the above process may each be performed separately, in one or more process lines separate from the production line for the remaining process. Alternatively or in addition, the sputter coating and/or laser etching steps may be performed separately. Some or all of the above steps may be performed in suitable roll-to-roll processes.

Details are now given for examples of some of the above processes. As indicated above, the patterning of the electrodes may include ablation of the electrode material to remove the electrode material between electrodes. The ablation may include removal of the electrode material through use of an excimer laser. For example, an XeCl excimer laser with a wavelength of 308 nm or a KRF excimer laser with a wavelength of 248 nm may be used to ablate the electrode material. The laser may provide a range of energy per pulse of 50-1000 mJ/cm , spectrally narrowed laser wavelengths with the difference between longer and shorter wavelengths being about 0.003 nm or less, large beam dimensions (e.g., 7 mm by 7 mm (about 50 mm²)). Further details of excimer laser ablation may be found in U.S. patent application Ser. No. 09/783,105, filed Feb. 14, 2001, titled “Multilayered Electrode/Substrate Structures and Display Devices Incorporating the Same,” and U.S. patent application Ser. No. 09/783,122, filed Feb. 14, 2001, titled “Multilayer Electrode/Substrate Structures and Liquid Crystal Devices Incorporating the Same,” both of which are herein incorporated by reference in their entireties. Alternatively or in addition, the patterning may include suitable conventional processes, such as wet etching.

Referring to FIG. 4, certain of the fabrication operations are schematically illustrated. A seal ring may be printed at appropriate locations on the webstock 160, by use of a printing device 176. The webstock 160 may then be spot-coated with adhesive material, such as a UV-curable adhesive material. The adhesive material may patterned to be located at the perimeter of the back panels 130 so that the panels may be later anchored to a web of back panels.

The position of the substrate film 112 on the webstock 160 may be registered, for example using a CCD camera 186 to detect a registration or alignment mark on or near the back panel 130. Then the back panel 130 is removed from a magazine 190 and placed on the substrate film 112 in a pick and place operation. The back panels 130 may be advanced to the front of the magazine 190 by a spring, and may be lightly retained for pick off by springy or mechanically retracting retainer fingers.

The pick and place operation may be performed by a pick and place device, which may include mechanical and/or vacuum grips to grip the back panel 130 while moving it into the desired location in alignment with the substrate film 112. It will be appreciated that a wide variety of suitable pick and place devices are well known. Examples of such devices are the devices disclosed in U.S. Pat. Nos. 6,145,901, and 5,564,888, both of which are incorporated herein by reference, as well as the prior art devices that are discussed in those patents. Alternatively, rotary placers may be utilized to place the back panel 130 upon the substrate film 112. An example of such a device is disclosed in U.S. Pat. No. 5,153,983, the disclosure of which is incorporated herein by reference.

The registration of the substrate film 112 may be coordinated with placement of the back panel 130 on the substrate film 112. For example, the CCD camera 186 and the pick and place device may be operatively coupled so as to insure alignment of the back panel 130 relative to the substrate film 112 during and/or after the placement of the front panel onto the back panel. It will be appreciated that use of the pick and place device allows greater accuracy in the placement of the back panel 130 relative to the substrate film 112, when compared to joining of front and back panels roll-to-roll processes involving combining respective front and back panel rolls. Devices produced by combining front and back panels from respective rolls may be prone to errors in alignment, due to the variations in dimension which may occur during fabrication of the front and back panels, variations in dimensions due to heating, stretching, and other processes involved in roll-to-roll fabrication.

It will be appreciated that the registration procedure described above may be changed and/or omitted if precise relative placement of the front panel 130 relative to the flexible substrate 112 is not required.

It will be appreciated that the back panels 130 must be sufficiently rigid so as to maintain sufficient dimensional stability and stiffness throughout the pick and place and registration processes. If the back panels 130 are too limp, they may flutter during the pick and place operation, interfering with proper position of the back panel 130 relative to the substrate film 112. As an example, a suitable Gurley stiffness of the front panels in the machine direction may be about 40 mg or above. Further information regarding acceptable stiffness for pick and place operations may be found in U.S. Pat. No. 6,004,682, the specification of which is incorporated herein by reference.

Thereafter, the back panel 130 is bonded to the substrate film 112. The bonding may be accomplished by using a UV light source 193 to spot cure the adhesive applied to the back panel 130. The spot coating and curing provides a way of quickly anchoring the back panel 130 and the substrate film 112 together, to maintain the desired relative alignment of the back panel 130 and the substrate film 112 during further processing steps.

Thereafter, the sealant rings of the combined front and back panels may be cured, such as by heating or by exposure to suitable radiation. Then, the combined front and back panels are cut and stacked, and are loaded into a magazine 195. Further steps, such as singulating the displays 10 and testing the displays, may then be performed.

The fabrications steps described above are merely one example of the fabrication of a display, and it will be appreciated that the above-described method may be suitably modified by adding, removing, or modifying steps or substeps.

The ridges or other protrusions may be physically and chemically integral to the substrate 112, and may be formed by a microreplication process. One technique of microreplicating arrays with very small surfaces requiring a high degree of accuracy is found in the use of continuous embossing to form cube corner sheeting. A detailed description of equipment and processes to provide optical quality sheeting are disclosed in U.S. Pat. Nos. 4,486,363 and 4,601,861. Tools and a method of making a tool used in those techniques are disclosed in U.S. Pat. Nos. 4,478,769; 4,460,449; and 5,156,863. The disclosures of all the above patents are incorporated herein by reference.

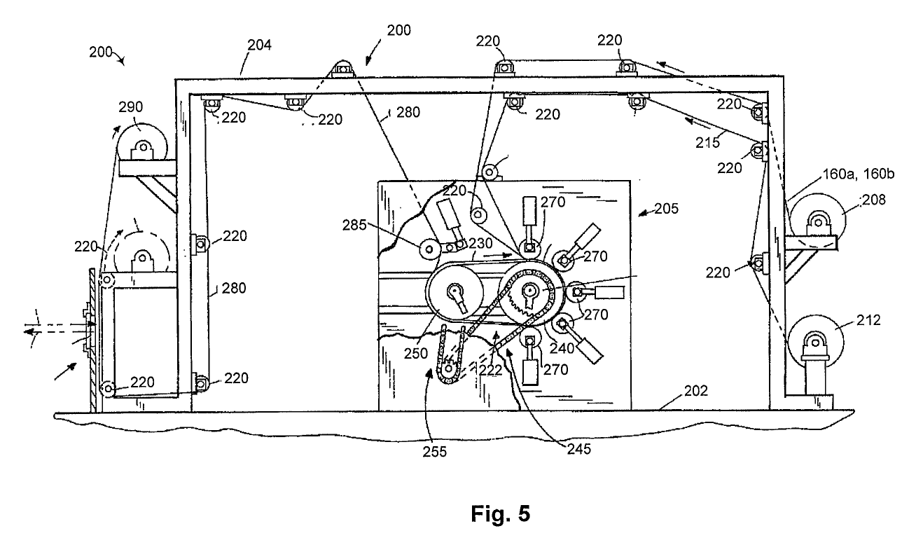

A machine 200 for producing a substrate such as that described above is shown in elevation in FIG. 5, suitably mounted on a floor 202. The machine 200 includes a frame 204, centrally located within which is an embossing means 205.

A supply reel 208 of unprocessed thermoplastic web 160a, 160b is mounted on the right-hand side of the frame 204; so is a supply reel 212 of flexible plastic film 215. An example of a suitable flexible plastic film 215 is a PET film available from DuPont, which is heat stabilized and has a glass transition temperature of 78 degrees C. and a use temperature of up to 120 degrees C. The flat web 160a, 160b and the film 215 are fed from the reels 208 and 212, respectively, to the embossing means 205, over guide rollers 220, in the direction of the arrows.

The embossing means 205 includes an embossing tool 222 in the form of an endless metal belt 230 which may be about 0.020 inches (0.051 cm) in thickness. The width and circumference of the belt 230 will depend in part upon the width or material to be embossed and the desired embossing speed and the thickness of the belt 230. The belt 230 is mounted on and carried by a heating roller 240 and a cooling roller 250 having parallel axes. The rollers 240 and 250 are driven by chains 245 and 255, respectively, to advance belt 230 at a predetermined linear speed in the direction of the arrow. The belt 230 is provided on its outer surface with a continuous female embossing pattern 260 that matches the general size and shape of the particular protrusions (such as the ridges 114) to be formed in the web 160a, 160b.

Evenly spaced sequentially around the belt, for about 180° around the heating roller 240, are at least three, and as shown five, of pressure rollers 270 of a resilient material, preferably silicone rubber, with a durometer hardness ranging from Shore A 20 to 90, but preferably, from Shore A 60 to 90.

While rollers 240 and 250 may be the same size, in the machine 200 as constructed, the diameter of heating roller 240 is about 10.5 inches (26.7 cm) and the diameter of cooling roller 250 is about 9 inches (22.9 cm). The diameter of each pressure roller 270 is about 6 inches (15.2 cm).

It may be desirable to maintain additional pressure about the tool and substrate during cooling, in which case the cooling roller 250 could be larger in diameter than the heating roller, and a plurality of additional pressure rollers, (not shown) also could be positioned about the cooling roller.

Either or both heating roller 240 or cooling roller 250, has axial inlet and outlet passages (not shown) joined by an internal spiral tube (not shown) for the circulation therethrough of hot oil (in the case of heating roller 240) or other material (in the case of cooling roller 250) supplied through appropriate lines (not shown).

The web 160a, 160b and the film 215, as stated, are fed to the embossing means 205, where they are superimposed to form a laminate 280 which is introduced between the belt 230 and the leading roller of the pressure rollers 270, with the web 160a, 160b between the film 215 and the belt 230. From thence, the laminate 280 is moved with the belt 230 to pass under the remaining pressure rollers 270 and around the heating roller 240 and from thence along belt 230 around a substantial portion of cooling roller 250. Thus, one face of web 160a, 160b directly confronts and engages embossing pattern 260 and one face of the film 215 directly confronts and engages pressure rollers 270.

The film 215 provides several functions during this operation. First, it serves to maintain the web 160a, 160b under pressure against the belt 230 while traveling around the heating and cooling rollers 240 and 250 and while traversing the distance between them, thus assuring conformity of the web 160a, 160b with the precision pattern 260 of the tool during the change in temperature gradient as the web (now embossed substrate) drops below the glass transition temperature of the material. Second, the film 215 maintains what will be the outer surface of substrate in a flat and highly finished surface for other processing, if desired. Finally, the film 215 acts as a carrier for the web 160a, 160b in its weak “molten” state and prevents the web from adhering to the pressure rollers 270 as the web is heated above the glass transition temperature.

The embossing means 205 finally includes a stripper roller 285, around which laminate 280 is passed to remove the same from the belt 230, shortly before the belt 230 itself leaves cooling roller 250 on its return path to the heating roller 240.

The laminate 280 is then fed from stripper roller 285 over further guiding rollers 220, eventually emerging from frame 204 at the lower left hand corner thereof. Laminate 280 is then wound onto a storage winder 290 mounted on the outside of frame 204 at the left hand end thereof and near the top thereof. On its way from the lower left hand corner of frame 204 to winder 290, additional guiding rollers guide the laminate 280.

The heating roller 240 is internally heated (as aforesaid) so that as belt 230 passes thereover through the heating station, the temperature of the embossing pattern 260 at that portion of the tool is raised sufficiently so that web 160a, 160b is heated to a temperature above its glass transition temperature, but not sufficiently high as to exceed the glass transition temperature of the film 215.

The cooling roller 250 is internally “fueled” (as aforesaid) so that as belt 230 passes thereover through the cooling station, the temperature of the portion of the tool embossing pattern 260 is lowered sufficiently so that web 160a, 160b is cooled to a temperature below its glass transition temperature, and thus becomes completely solid prior to the time laminate 280 is stripped from tool 230.

It has been found that the laminate 280 can be processed through the embossing means 205 at the rate of about 3 to 4 feet per minute, with satisfactory results in terms of the accuracy and dimensional stability and other pertinent properties of the finished substrate.

It will further understood that temperatures of the heating roller and cooling rollers may need to be adjusted within certain ranges depending upon the web material selected. Certain materials have higher glass transition temperature T_{G} than others. Others may require cooling at a higher temperature then normal and for a longer time period. Preheating or additional heating at the entrance of the nips may be accomplished by a laser, by flameless burner, or by another device, and/or by adjusting the temperature of the heating roller to run at higher preselected temperature. Similar adjustments may be made at the cooling level.

A preferred material for the embossing tool disclosed herein is nickel. The very thin tool (about 0.010 inches (0.025 cm) to about 0.030 inches (0.076 cm)) permits the rapid heating and cooling of the tool 230, and the web 160a, 160b, through the required temperatures gradients while the pressure rolls and the carrier film apply pressure. The result is the continuous production of a precision pattern where flatness and angular accuracy are important while permitting formation of sharp corners with minimal distortion of other surfaces, whereby the finished substrate provides an array of protrusions (such as the ridges 114) formed with high accuracy.

The embossing means described herein, with suitable modifications of the tooling, substrate materials and process conditions, may be used to produce any of a a variety of types of protrusions.

An alternative method of forming the protrusions such as the ridges 114 is by printing UV-curable resins on a substrate, and then curing the resins to form the protrusions. An example of a suitable material is a black matrix material commonly used in making color filters, such as the OPTIMER CR Series Pigment Dispersed Color Resist available from JSR Corporation of Japan. Another example of UV-curable resins is UV-curable epoxy acrylates. The printing may be accomplished by ink jet printing or screen printing, for example. Further information regarding ink jet printing and screen printing may be found in U.S. Pat. No. 5,889,084, and U.S. Pat. No. 5,891,520, the disclosures of which are incorporated herein by reference. Other methods of forming microstructures with UV-curable resins may be found in International Publication No. WO 99/08151.

A further method of forming a substrate element includes forming protrusions on a major surface of a substrate by a photolithography process. The photoresist for the photolithography process may be a black matrix material of the type commonly used for producing color filters. A preferred material of this type is CSP series photo-sensitive rib materials by Fuji Film Olin Co., Ltd (Japan).

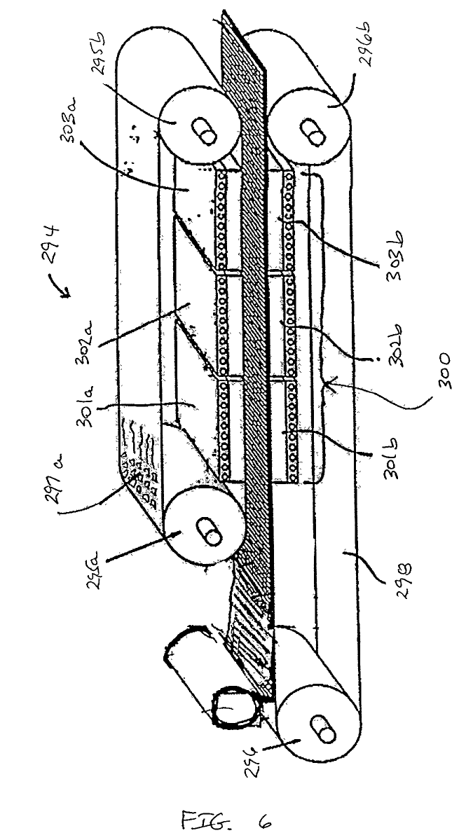

It will be appreciated that a structure or arrangement of protrusions and recesses may also be formed on a rigid substrate, by use of suitable methods and/or equipment. For example, the above-described methods involving printing and curing UV-curable resins, and photolithography, may be utilized. As another alternative, a suitable embossing process may be used to form the arrangement of recesses and protrusions. A press 294 for carrying out an embossing process on rigid substrates is shown in FIG. 6, and its operation is described briefly below. Further details regarding embossing of rigid materials may be found in commonly-assigned, co-pending U.S. patent application Ser. No. 09/596,240, entitled “A Process for Precise Embossing”, filed Jun. 6, 2000, and in International Application PCT/US01/18655, filed Jun. 8, 2001. Both of these applications are incorporated herein by reference in their entireties.

Continuous presses, of which the press 294 of FIG. 6 is an example, include double band presses which have continuous flat beds with two endless bands or belts, usually steel, running above and below the product and around pairs of upper and lower drums or rollers. These form a pressure or reaction zone between the two belts and advantageously apply pressure to a product when it is flat rather than when it is in a curved form. The double band press also allows pressure and temperature to vary over a wide range. Dwell time or time under pressure is easily controlled by varying the production speed or rate, and capacity may be changed by varying the speed, length, and/or width of the press.

In use, the product is “grabbed” by the two belts and drawn into the press at a constant speed. At the same time, the product, when in a relatively long flat plane, is exposed to pressure in a direction normal to the product. Of course, friction is substantial on the product, but this may be overcome by one of three systems. One system is the gliding press, where pressure-heating plates are covered with low-friction material such as polytetrafluoroethylene and lubricating oil. Another is the roller bed press, where rollers are placed between the stationary and moving parts of the press. The rollers are either mounted in a fixed position on the pressure plates or incorporated in chains or roller “carpets” moving inside the belts in the same direction but at half speed. The roller press is sometimes associated with the term “isochoric.” This is because the press provides pressure by maintaining a constant distance between the two belts where the product is located. Typical isochoric presses operate to more than 700 psi.

A third system is the fluid or air cushion press, which uses a fluid cushion of oil or air to reduce friction. The fluid cushion press is sometimes associated with the term “isobaric” and these presses operate to about 1000 psi. Pressure on the product is maintained directly by the oil or the air. Air advantageously provides a uniform pressure distribution over the entire width and length of the press.

In double band presses, heat is transferred to thin products from the heated rollers or drums via the steel belts. With thicker products, heat is transferred from heated pressure plates to the belts and then to the product. In gliding presses, heat is also transferred by heating the gliding oil itself. In roller bed presses, the rollers come into direct contact with the pressure-heating plates and the steel belts. In air cushion presses, heat flows from the drums to the belts to the product, and, by creating turbulence in the air cushion itself, heat transfer is accomplished relatively efficiently. Also, heat transfer increases with rising pressure.

Another advantage of the double band press is that the product may be heated first and then cooled, with both events occurring while the product is maintained under pressure. Heating and cooling plates may be separately located one after the other in line. The belts are cooled in the second part of the press and these cooled belts transfer heat energy from the product to the cooling system fairly efficiently.

Continuous press machines fitting the general description provided hereinabove are sold by Hymmen GmbH of Bielefeld, Germany (U.S. office: Hymmen International, Inc. of Duluth, Ga.) as models ISR and HPL. These are double belt presses and also appear under such trademarks as ISOPRESS and ISOROLL. To applicants' knowledge, such presses heretofore have not generally been used to emboss precise recesses, especially with polymeric materials.

Using the press in forming an arrangement of protrusions and recesses on a rigid substrate, such as a thermoplastic substrate, involves the following steps: providing a continuous press with an upper set of rollers, a lower set of rollers, an upper belt disposed about the upper set of rollers, a lower belt disposed about the lower set of rollers, a heating station, a cooling station, and pressure producing elements; passing an amorphous thermoplastic material through the press; heating the material to about 490° F. (255° C.); applying pressure of at least about 250 psi (17 bars) to the material; cooling the material to near its T_{g}and, if desired, maintaining pressure on the material while the material is cooled.

Making reference to FIG. 6, details of the press 294 are now described. The press 294 includes a pair of upper rollers 295a, 295b and a pair of lower rollers 296a, 296b. The upper roller 295a and the lower roller 296a may be oil heated. Typically the rollers are about 31.5 inches in diameter and extend for about 27.5 inches (70 cm). Around each pair of rollers is a steel (or nickel) belt 297, 298. An upper patterned belt 297 is mounted around the upper rollers 295a, 295b and a lower plain belt 298 is mounted around the lower rollers 296a, 296b. Only a portion of the pattern is illustrated, but it is understood that it will contain an array of male elements designed to provide the necessary size and shape of the receptor recesses 291. These belts may be generally similar to those continuous belts described above in conjunction with the continuous roll embossing process, for machine 200 (FIG. 5).

Heat and pressure are applied in a portion of the press referred to as the reaction zone 300. Within the reaction zone are means for applying pressure and heat, such as three upper matched pressure sections 301a, 302a, 303a and three lower matched pressure sections 301b, 302b, 303b. Each section is about 39 inches (100 cm) long and the width depends on the width of roll desired, one example being 27.5 inches (70 cm). Heat and pressure may be applied in other ways that are well known by those skilled in the art. Also, it is understood that the dimensions set forth are for existing or experimental continuous presses, such as those manufactured by Hymmen; these dimensions may be changed if desired.

The lower belt 298 will be smooth if only one side of a product is to be embossed. It is to be understood that the pressure sections may be heated or cooled. Thus, for example, the first two upstream pressure sections, upper sections 301a, 302a and the first two lower sections 301b, 302b may be heated whereas the last sections 303a and 303b may be cooled or maintained at a relatively constant but lower temperature than the heated sections.

Thermoplastic materials such as polysulfone, polyarylate, high T_{g} polycarbonate, polyetherimide, and copolymers may be used in the press 294 (or the embossing machine 200). With such material, the pressure range is approximately 180 to 1430 psi and the temperature range is approximately 485° F. to 580° F. (250° C. to 340° C.). Material thicknesses of 75 μm to 250 μm may be embossed to provide the desired receptor recesses.

With the dimensions and reaction zones stated above, the process rate may move at about 21 to 32 feet per minute.

As discussed above, the embossing machine 200 shown in FIG. 5 would generally be suitable for use with relatively flexible materials, while the press 294 shown in FIG. 6 would generally be suitable for use with relatively rigid materials. The choice as to which type of microreplicating machine to employ may depend on the thickness and elasticity modulus of the material to be microreplicated. For example, polycarbonate has a modulus of elasticity of 10⁸ Pascals, as determined according to ASTM D882. Films of polycarbonate less than about 15 mils thick would preferably be run through a belt embosser, while films of polycarbonate greater than about 30 mils thick would preferably be run through a flat bed embosser. For materials with vary low elasticity modulus, such as a rubbery foam, the upper limit of thickness for a belt embosser would be higher.

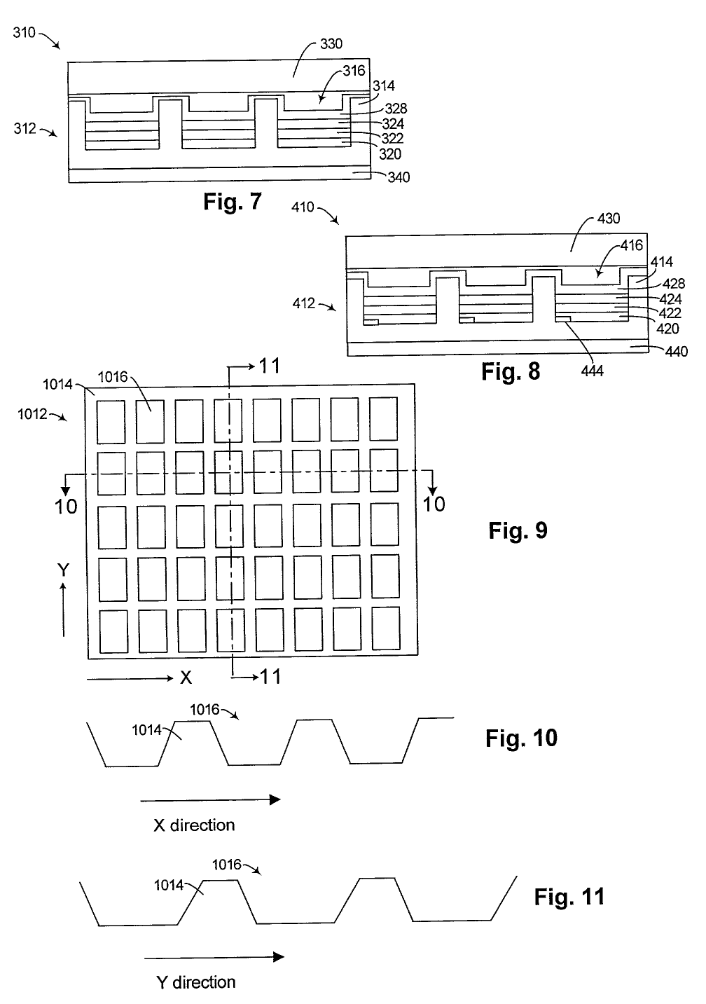

An alternative passive matrix PLED display device 310 is shown in FIG. 7. Components/features 312-330 correspond to components/features 112-130 of the display device 110 shown in FIG. 3 and described above. However, in the display device 310 the light from the LEP 324 exits the display through the front panel 330. Thus the front panel 330 and the cathode 328 are sufficiently transparent to allow light to pass therethrough. The front panel may be transparent glass. The cathode 328 may be a low work function electrode material. Examples of transparent, low work function electrodes may be found in U.S. Pat. No. 6,150,043, which is incorporated herein by reference in its entirety.

The substrate film 312 forms part of the back panel of the display device 310. The substrate film 312 may be laminated to a metal foil 340, to provide good barrier properties and enhanced reflectivity and/or contrast. The metal foil 340 may be an aluminum foil, a copper foil, or a stainless steel foil, for example.

The anode 322 need not be transparent, and may be a patterned metal electrode, such as an electrode including aluminum, copper, or ITO, for example.

FIG. 8 shows an active matrix PLED 410. Except as discussed below, the components/features 412-440 may correspond to the components/features of the display device 310 shown in FIG. 7 and described above.

The PLED 410 includes a continuous cathode layer 428. Each of the anodes 420 has a corresponding thin film transistor (TFT) 444. The TFT 444 is used in selectively providing power to the corresponding anode 420. The TFT may be a polysilicon TFT. Alternatively, the TFT 444 may be a printed organic semiconductor TFT.

The substrate film 412 may be coated with polyimide to improve thermal resistance. Polyimide-coated films are described further in International Publication WO 00/41884, which is incorporated herein by reference in its entirety.

Steps in manufacture of the display 410 may include the following steps: 1) microreplicate the substrate film 412 to form the ridges 414 and the wells 416; 2) sputter coat the material for the anodes 420; 3) laser etch to remove the anode material from the tops and sides of the ridges 414; 4) form the TFTs 444 in the wells 416; 5) inkjet print the hole transport layer 422 in the wells 416; 6) inkjet print the LEP 424 in the wells 416; 7) sputter deposit the material for the cathodes 428; 8) printing the sealant; 9) laminating the back panel 430 onto the ridges 414 by a pick and place operation; 10) curing the sealant; and 11) cutting the finished display device 410, separating it from a roll including multiple such devices.

FIGS. 9-13 illustrate some steps of a process for making the PLED devices such as those described above. FIG. 9 shows a substrate film 1012 with wells 1016 thereupon formed by microreplication. FIGS. 10 and 11 show cross-sections of the film, showing one possible tapered shape of the ridges 1014 bounding the wells 1016.

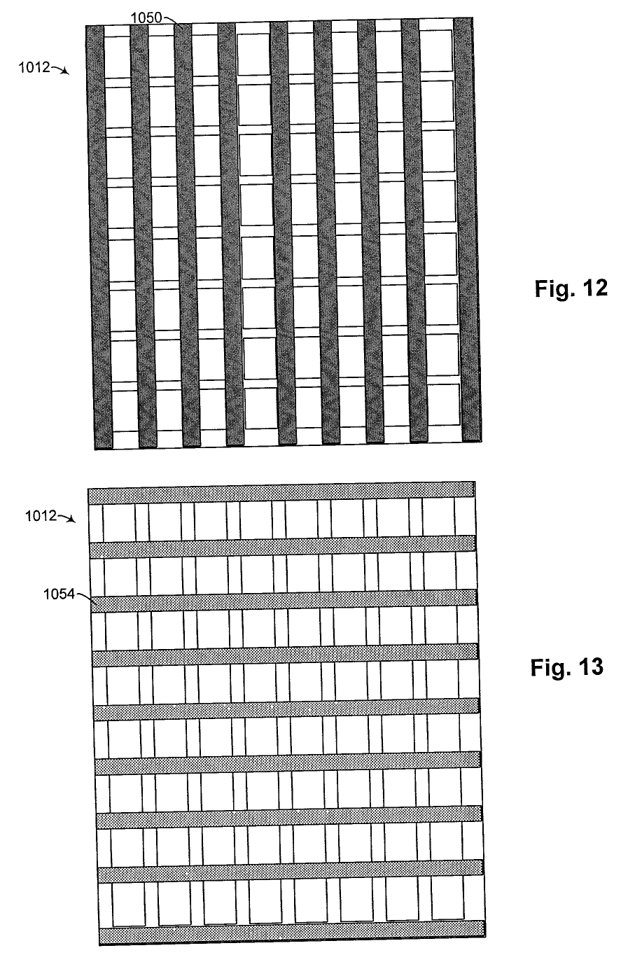

For passive matrix displays such as those of FIGS. 3 and 7, following deposition of the anode electrode material (e.g., ITO), the electrode material is selectively etched to remove it from the shaded areas 1050 shown in FIG. 12. As discussed above, the etching may be wet etching, for example utilizing patterning by a photolithography process to achieve the desired selective etching. Alternatively, the etching may be dry etching, such as excimer laser etching.

After deposition of the hole transporting and LEP layers, such as by printing, and before depositing the cathode material, an insulator, such as SiO₂, may be selectively deposited, for example being deposited in the shaded areas 1054 shown in FIG. 13. The insulator may reduce the occurrence of electrical shorting in the display device.

As another alternative manufacturing method, after microreplication of a substrate film such as the substrate film 1012, the bottom of the film may be cut off, thus transforming the wells 1016 into holes through the film. Then the film may be adhered to a glass or other rigid substrate with patterned electrodes (such as ITO electrodes) already formed thereupon. It will be appreciated that the substrate film 1012 may be suitable registered so as to desirably align the holes with the patterned electrodes.

Displays of the sort described above may be coupled to other components as a part of a wide variety of devices, for display of various types of information. For example, a display may be coupled to a microprocessor, as part of a computer, electronic display device such as an electronic book, cell phone, calculator, smart card, appliance, etc., for displaying information.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

What is claimed is:

1. An electroluminescent display comprising:
a first substrate having protrusions on a major surface thereof;
a second substrate resting at least partially on the protrusions; and
a plurality of pixels between the substrates, each of the pixels including a light emitting material between a pair of electrodes.

2. The display of claim 1, wherein the display is a passive matrix display.

3. The display of claim 2, wherein the electrodes include row electrodes and column electrodes.

4. The display of claim 1, wherein the display is an active matrix display.

5. The display of claim 4, wherein one of the substrates includes a plurality of thin film transistors, each of the transistors corresponding to a respective pixel.

6. The display of claim 1, wherein the protrusions include ridges surrounding each of a plurality of recesses.

7. The display of claim 6, wherein the pixels are in respective of the recesses.

8. The display of claim 1, wherein the protrusions have tapered sides.

9. The display of claim 1, wherein the protrusions are physically and chemically integral with the first substrate.

10. The display of claim 9, wherein the protrusions are embossed on the first substrate.

11. The display of claim 9, wherein the protrusions are formed by photolithography.

12. The display of claim 1, wherein the protrusions are not physically and chemically integral with the first substrate.

13. The display of claim 12, wherein the protrusions are made of a curable resin.

14. The display of claim 12, wherein the protrusions are adhered to the first substrate.

15. The display of claim 14, wherein the protrusions are in the form of a sheet of protrusions adhered to the first substrate.

16. The display of claim 1, wherein the light emitting material includes a hole transport material.

17. The display of claim 16, wherein the hole transport material has a thickness from 100 to 500 Angstroms.

18. The display of claim 17, wherein the light emitting material further includes an electron transport material.

19. The display of claim 18, wherein the electron transport material has a thickness from 100 to 500 Angstroms.

20. The display of claim 16, wherein the light emitting material does not include an electron transport material.

21. The display of claim 16, wherein the light emitting material further includes an emitter.

22. The display of claim 21, wherein the emitter has a thickness from 50 to 100 Angstroms.

23. The display of claim 16, wherein the light emitting material includes a semiconductor material.

24. The display of claim 16, wherein the light emitting material includes an organic compound.

25. The display of claim 16, wherein the light emitting material includes a light emitting polymer.

26. The display of claim 25, wherein the light emitting polymer has a thickness from 20 to 60 nm.

27. The display of claim 1, wherein the first substrate is a rigid substrate.

28. The display of claim 27, wherein the second substrate is also rigid.

29. The display of claim 27, wherein the second substrate is a flexible substrate.

30. The display of claim 27, wherein the first substrate is a plastic substrate.

31. The display of claim 27, wherein the first substrate is a glass substrate.

32. The display of claim 1, wherein the fist substrate is a flexible substrate.

33. The display of claim 32, wherein the second substrate is also a flexible rigid.

34. The display of claim 32, wherein the second substrate is a rigid substrate.

35. The display of claim 32, wherein the flexible substrate includes a polymer material.

35. The display of claim 32, wherein the wherein the flexible substrate is opaque.

36. The display of claim 35, wherein the flexible substrate is black.

37. The display of claim 35, wherein the flexible substrate includes an opaque material layer and a transparent layer.

38. The display of claim 37, wherein the opaque material layer and the transparent layer are both polymer material layers.

39. A method of making an electroluminescent display device, the method comprising:
forming a pair of panels, wherein one of the panels includes overlapping electrodes with light emitting material therebetween, the electrodes and the light emitting material thereby forming a plurality of pixels, and wherein at least one of the panels includes protrusions; and
joining the panels together such that the protrusion maintain a space between opposing major surfaces of the panels, with the electrodes and the light emitting material between the major surfaces of the panels.

40. The method of claim 39, wherein the forming the panels includes forming a first panel that includes the protrusions, the electrodes, and the light emitting material.

41. The method of claim 40, wherein the electrodes include a first set of electrodes and a second set of electrodes, and wherein the forming the first panel includes:
forming the protrusions on a substrate;
forming the first set of electrodes on the substrate;
depositing the light emitting material on the first set of electrodes; and
forming the second set of electrodes on the light emitting material.

42. The method of claim 41, wherein the forming the protrusions includes microreplicating the protrusions on a roll of flexible substrate material.

43. The method of claim 42, wherein the microreplicating includes embossing the protrusions.

44. The method of claim 41, wherein the joining includes placing a rigid second panel on the first panel while the first panel is attached to the roll of substrate material.

45. The method of claim 44, wherein the placing includes placing the panel using a pick and place device.

46. The method of claim 44, further comprising, after the joining, separating the display from the roll of substrate material.

47. The method of claim 41, wherein the substrate is a rigid substrate

48. The method of claim 41, wherein the forming the protrusions includes forming ridges surrounding wells.

49. The method of claim 48, wherein the pixels are formed in respective of the wells.

50. The method of claim 41, wherein the forming of the sets of electrodes each includes depositing electrode material and selectively removing some of the electrode material.

51. The method of claim 50, wherein depositing includes sputter coating the electrode material onto the first panel.

52. The method of claim 50, wherein the selectively removing includes wet etching.

53. The method of claim 50, wherein the selectively removing includes dry etching.

54. The method of claim 53, wherein the dry etching includes laser etching.

55. The method of claim 41, wherein the depositing the light emitting material includes printing the light emitting material.

56. The method of claim 41, further comprising, after the depositing the light emitting material and before forming the second set of the electrodes, selectively depositing an insulator.

57. The method of claim 56, wherein the selectively depositing the insulator includes selectively depositing SiO₂.

58. The method of claim 40, wherein the forming the first panel includes:
forming the electrodes and the light emitting material on a first substrate; and
adhering a protrusion film to the first substrate, on top of the electrodes and the light emitting material.

59. The method of claim 58, further comprising, prior to the adhering, forming the protrusion film.

60. The method of claim 59, wherein the forming the protrusion film includes microreplicating a polymer material, and removing a portion of the material to produce openings in the film.

61. The method of claim 40, wherein the display is a passive matrix display.

62. The method of claim 61, wherein the electrodes include a set of row electrodes and a set of column electrodes, wherein the sets overlap.

63. The method of claim 40, wherein the display is an active matrix display.

64. The method of claim 63, further comprising imbedding driving electronics in one of the panels.

65. The method of claim 64, wherein the driving electronics include a plurality of thin film transistors, each of the transistors corresponding to a respective of the pixels.

66. The method of claim 40, wherein the light emitting material includes a hole transport material.

67. The method of claim 66, wherein the hole transport material has a thickness from 100 to 500 Angstroms.

68. The method of claim 66, wherein the light emitting material further includes an electron transport material.

69. The method of claim 68, wherein the electron transport material has a thickness from 100 to 500 Angstroms.

70. The method of claim 66, wherein the light emitting material does not include an electron transport material.

71. The method of claim 66, wherein the light emitting material further includes an emitter.

72. The method of claim 71, wherein the emitter has a thickness from 50 to 100 Angstroms.

73. The method of claim 66, wherein the light emitting material includes a semiconductor material.

74. The method of claim 66, wherein the light emitting material includes an organic compound.

75. The method of claim 66, wherein the light emitting material includes a light emitting polymer.

76. The method of claim 75, wherein the light emitting polymer has a thickness from 20 to 60 nm.

77. The method of claim 40, wherein the joining includes curing a sealant ring between the panels.

78. The method of claim 77, wherein the joining further includes curing a spot coated adhesive earlier applied to one of the panels.
